(19) United States
(12) Patent Application Publication
(10) Pub. No.: US 2024/0096633 A1
(43) Pub. Date: Mar. 21, 2024

(54) METHODS AND ASSEMBLIES FOR SELECTIVELY DEPOSITING TRANSITION METALS

(71) Applicant: ASM IP Holding B.V., Almere (NL)

(72) Inventors: Elina Färm, Helsinki (FI); Jan Willem Maes, Wilrijk (BE); Charles Dezelah, Helsinki (FI); Shinya Iwashita, Brussels (BE); Arpita Saha, Kolkata (IN); Eva Tois, Espoo (FI); Marko Tuominen, Helsinki (FI); Janne-Petteri Niemelä, Helsinki (FI); Patricio Eduardo Romero, Wilsele (BE); Chiyu Zhu, Helsinki (FI); Glen Wilk, Scottsdale, AZ (US); Holger Saare, Scottsdale, AZ (US); YoungChol Byun, Tempe, AZ (US); Jonahtan Bakke, Phoenix, AZ (US)

(21) Appl. No.: 18/367,500

(22) Filed: Sep. 13, 2023

Related U.S. Application Data
(60) Provisional application No. 63/407,200, filed on Sep. 16, 2022.

(51) Int. Cl. H01L 21/285; C23C 16/18; C23C 16/455; C23C 16/56

(52) U.S. Cl. CPC H01L 21/28568; C23C 16/18; C23C 16/45527; C23C 16/56

(57) ABSTRACT

The disclosure relates to methods of selectively depositing material comprising a group 3 to 6 transition metal on a first surface of a substrate relative to a second surface of the substrate by a cyclic deposition process. The method includes providing a substrate in a reaction chamber, providing a transition metal precursor into the reaction chamber in a vapor phase, wherein the transition metal precursor comprises an aromatic ligand and providing a second precursor into the reaction chamber in a vapor phase to deposit transition metal on the first surface of the substrate. The disclosure further relates to a transition metal layers, and to deposition assemblies.

### CROSS-REFERENCE TO RELATED APPLICATIONS

This application claims priority to and the benefit of U.S. Provisional Application No. 63/407,200, filed Sep. 16, 2022, the entirety of which is incorporated by reference herein.

### FIELD

The present disclosure relates to methods and apparatuses for the manufacture of semiconductor devices. More particularly, the disclosure relates to methods and assemblies for depositing material comprising a transition metal on a substrate, and layers comprising a transition metal.

### BACKGROUND

Semiconductor device fabrication processes generally use advanced deposition methods for forming metal-comprising layers with specific properties. Transition metals are useful for a range of semiconductor applications. Transition metals in groups 3 (scandium, yttrium), 4 (titanium, zirconium, hafnium), 5 (vanadium, niobium, tantalum) and 6 (chromium, molybdenum and tungsten) may have many of the advantages sought in the art. For example, they may be useful as a conductor material in back end of line (BEOL) or mid end of line (MEOL) applications, or in in metal gate applications.

The selective deposition of metallic thin films by atomic layer deposition remains challenging, especially to deposit high-quality films containing electropositive elements, and metals that readily form unwanted phases, such as carbides. Further, area-selective deposition of transition metals is sought after to enable more elaborate fabrication of semiconductor devices, while keeping the number of processing steps feasible and/or cost-effective. Thus there is need in the art for alternative or improved methods for depositing transition metals or transition metal-containing layers selectively.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of depositing a material comprising a transition metal on a substrate selectively, to a transition metal layer, to a semiconductor structure and a device, and to deposition assemblies for selectively depositing material comprising a transition metal on a substrate.

In one aspect, a method of selectively depositing material comprising a group 3 to 6 transition metal on a first surface of a substrate relative to a second surface of the substrate by a cyclic deposition process is disclosed. The method comprises providing a substrate in a reaction chamber, providing a transition metal precursor into the reaction chamber in a vapor phase, wherein the transition metal precursor comprises an aromatic ligand and providing a second precursor into the reaction chamber in a vapor phase to deposit transition metal on the first surface of the substrate.

In some embodiments, the transition metal precursor comprises a benzene or a cyclopentadienyl group. In some embodiments, the transition metal precursor comprises only a transition metal, carbon and hydrogen. In some embodiments, the transition metal precursor comprises a methylbenzene ligand. In some embodiments, the transition metal precursor comprises an ethylbenzene ligand.

In some embodiments, the second precursor comprises a reducing agent. In some embodiments, the reducing agent comprises molecular hydrogen (H₂). In some embodiments, the second precursor comprises a silane, such as an alkylsilane. In some embodiments, the silane is a disilane. In some embodiments, the silane comprises hexamethyl disilane.

In some embodiments, the second precursor comprises a halogen. In some embodiments, the halogen is selected from a group consisting of iodine and bromine. In some embodiments, the second precursor comprises an organic group. In some embodiments, the second precursor comprises a halogenated hydrocarbon. In some embodiments, the halogenated hydrocarbon comprises two or more halogen atoms selected from iodine and bromine. In some embodiments, the at least two halogen atoms are attached to different carbon atoms. In some embodiments, two of the halogen atoms in the halogenated hydrocarbon are attached to adjacent carbon atoms of a carbon chain. In some embodiments, the halogenated hydrocarbon is a 1,2-dihaloalkane or 1,2-dihaloalkene or 1,2-dihaloalkyne or 1,2-dihaloarene. In some embodiments, the two halogen atoms of the halogenated hydrocarbon are the same halogen. In some embodiments, the halogenated hydrocarbon is 1,2-diiodoethane.

In some embodiments, the second precursor is a nitrogen precursor. In some embodiments, the nitrogen precursor is selected from a group consisting of NH₃, NE₂NH₂, and mixture of gaseous H₂ and N₂.

In some embodiments, the first surface is a metal or metallic surface. In some embodiments, the metal or metallic surface is selected from a group consisting of Mo, W, Ru, Co, Cu, TiN, VN and TiC. In some embodiments, the first surface is a conductive surface. In some embodiments, the first surface may comprise surface oxidation at the beginning of the deposition process. In some embodiments, the surface oxidation may be removed during performing of the method according to the current disclosure.

In some embodiments, the second surface is a dielectric surface. In some embodiments, the dielectric surface comprises silicon. In some embodiments, the second surface is a silicon oxide-based surface. In some embodiments, the dielectric surface is a low k surface. In some embodiments, the second surface comprises carbon (e.g. methyl) terminations.

In some embodiments, the second surface is treated with a passivating agent before providing the transition metal precursor into the reaction chamber. In some embodiments, the passivating agent comprises a silylating agent. In some embodiments, the silylating agent is selected from a group comprising allyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS) and N-(trimethylsilyl)dimethylamine (TMSDMA).

In some embodiments, the cyclic deposition process comprises a thermal deposition process. In some embodiments, the cyclic deposition process comprises purging the reaction chamber after providing a transition metal precursor into the reaction chamber. In some embodiments, transition metal is deposited on the first surface of the substrate as a layer. In some embodiments, the transition metal is molybdenum, and the transition metal is selectively deposited on a metal surface inside a feature.

In another aspect, a transition metal layer comprising a group 3 to 6 transition metal deposited on a first surface of a substrate relative to a second surface of the substrate by a cyclic deposition process is disclosed, wherein the process comprises providing a substrate in a reaction chamber, providing a transition metal precursor into the reaction chamber in a vapor phase, wherein the transition metal precursor comprises an aromatic ligand and providing a second precursor into the reaction chamber in a vapor phase to deposit transition metal on the first surface of the substrate.

In some embodiments, the transition metal layer has a carbon content of less than about 20 at. %.

In a further aspect, a semiconductor structure comprising a group 3 to 6 transition metal deposited by a cyclic deposition process on a first surface of a substrate relative to a second surface of the substrate is disclosed, wherein the process comprises providing a substrate in a reaction chamber, providing a transition metal precursor into the reaction chamber in a vapor phase, wherein the transition metal precursor comprises an aromatic ligand and providing a second precursor into the reaction chamber in a vapor phase to deposit transition metal selectively on the first surface of the substrate relative to the second surface of the substrate.

In a further aspect, a semiconductor device comprising a group 3 to 6 transition metal deposited by a cyclic deposition process on a first surface of a substrate relative to a second surface of the substrate is disclosed, wherein the process comprises providing a substrate in a reaction chamber, providing a transition metal precursor into the reaction chamber in a vapor phase, wherein the transition metal precursor comprises an aromatic ligand and providing a second precursor into the reaction chamber in a vapor phase to deposit transition metal selectively on the first surface of the substrate relative to the second surface of the substrate.

In yet another aspect, a vapor processing assembly for selectively depositing material comprising a group 3 to 6 transition metal on a first surface of a substrate relative to a second surface of the substrate is disclosed. The vapor processing assembly comprises one or more reaction chambers constructed and arranged to hold the substrate, a precursor injector system constructed and arranged to provide a transition metal precursor comprising an aromatic ligand and a second precursor into the reaction chamber in a vapor phase. The vapor processing assembly further comprises a precursor vessel constructed and arranged to contain a transition metal precursor comprising an aromatic ligand, and the vapor processing assembly is constructed and arranged to provide the transition metal precursor and the second precursor via the precursor injector system to the reaction chamber to deposit material comprising transition metal selectively on the first surface of the substrate relative to the second surface of the substrate. I some embodiments, the vapor processing assembly further comprises a passivating agent source constructed and arranged to contain a passivating agent for passivating the second surface of the substrate, and wherein the precursor injector system is constructed and arranged to provide the passivating agent into the reaction chamber in vapor phase. In some embodiments, the vapor processing assembly comprises a second precursor vessel constructed and arranged to contain a second precursor.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments. The headings provided herein, if any, are for convenience only and do not necessarily affect the scope or meaning of the claimed invention.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1, panels A and B, is a block diagram of exemplary embodiments of method according to the current disclosure.

FIG. 2 is a schematic presentation of a transition metal layer deposited according to the current disclosure on a first surface of a substrate relative to a second surface of the same substrate.

FIG. 3 is a schematic presentation of a vapor processing assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the current disclosure.

### DETAILED DESCRIPTION

The description of exemplary embodiments of methods, structures, devices and deposition assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

### General Process

In one aspect, a method of selectively depositing material comprising a group 3 to 6 transition metal on a first surface of a substrate relative to a second surface of the substrate by a cyclic deposition process is disclosed. In some embodiments, material comprising a group 3 transition metal is deposited. Group 3 transition metals include scandium (Sc), yttrium (Y) and lanthanum (La). In some embodiments, material comprising a group 4 transition metal is deposited. Group 4 transition metals include titanium (Ti), zirconium (Zr) and hafnium (Hf). In some embodiments, material comprising a group 5 transition metal is deposited. Group 5 transition metals include vanadium (V), niobium (Nb) and tantalum (Ta). In some embodiments, material comprising a group 6 transition metal is deposited. Group 6 transition metals include chromium (Cr), molybdenum (Mo) and tungsten (W). In some embodiments, material comprising Mo is deposited. In some embodiments, material comprising V is deposited. In some embodiments, material comprising Ti is deposited.

However, in an additional aspect, a transition metal from groups 7 to 10 of the periodic table of elements may be used. For example, ruthenium (Ru), nickel (Ni) or copper (Cu) may be used. In some embodiments, a transition metal from group 8 is used. In some embodiments, a transition metal from group 9 is used. In some embodiments, a transition metal from group 10 is used. In some embodiments, material comprising Ru is deposited.

The methods according to the current disclosure comprise providing a substrate in a reaction chamber, providing a transition metal precursor into the reaction chamber in a vapor phase, wherein the transition metal precursor comprises an aromatic ligand and providing a second precursor into the reaction chamber in a vapor phase to deposit transition metal on the first surface of the substrate.

### Selectivity

The current disclosure relates to a selective deposition process. Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition is inherent, and no additional processing steps over those conveniently performed on a substrate are necessary. However, in some embodiments, the second surface may be passivated before depositing the material comprising a transition metal on the first surface. Selectivity may be inherent to a certain thickness of deposited material, and be lost in case deposition is continued beyond a process-specific threshold. Thus, it may be possible to deposit a material layer of, for example, about 1 nm, about 2 nm, about 3 nm, about 5 nm or about 6 nm before selectivity is lost. If thicker material layers are desired, the contrast between the first surface and the second surface may be enhanced though passivating the second surface. Alternatively or in addition, intermittent etch-back phase using, for example plasma, such as hydrogen plasma, may be used to keep selectivity.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device. A substate according to the current disclosure comprises a first surface and a second surface. The first surface and the second surface have different material properties, allowing for the selective deposition of a material comprising as transition metal on the first surface.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, the substrate surface is exposed to argon/hydrogen plasma. In some embodiments, a pretreatment or cleaning process may be carried out in the same reaction chamber as a selective deposition process. However, in some embodiments, a pretreatment or cleaning process may be carried out in a separate reaction chamber.

In some embodiments, cleaning chemicals, such as hexafluoroacetylacetone, other β-diketonates or carboxylic acids, sucha as formic acid, may be used in cleaning the substrate.

### First Surface

According to some aspects of the present disclosure, selective deposition can be used to deposit a material comprising a transition metal on the first surface relative to the second surface of the substrate.

In some embodiments, the first surface is a metal or metallic surface. In some embodiments, the first surface comprises, consists essentially of, or consists of, a metal nitride, such as TiN or VN. In some embodiments, the first surface comprises, consists essentially of, or consists of, a metal carbide, such as titanium carbide.

In some embodiments, a material comprising a transition metal is selectively deposited on a first surface comprising a metal or a metallic material relative to another surface. In some embodiments, a material comprising a transition metal, such as metallic molybdenum, is selectively deposited on a first conductive surface (such as a metal or metallic surface) of a substrate relative to a second dielectric surface of the substrate.

In some embodiments, a material comprising a transition metal, such as material comprising a group 3, group 4, group 5 or group 6 transition metal, is selectively deposited on a first metal or metallic surface of a substrate relative to a second, low k surface. In some embodiments, a passivation agent, such as silylation, is used to improve contrast between the first metal or metallic surface and second silicon-based dielectric surface before depositing the material comprising a transition metal on the first surface.

For embodiments in which the first surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal nitrides, metal carbides and/or mixtures thereof. In some embodiments the metal or metallic surface may comprise surface oxidation. In some embodiments, the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises Cu. In some embodiments, a metal or metallic surface comprises Co. In some embodiments, a metal or metallic surface comprises W. In some embodiments, a metal or metallic surface comprises Ru. In some embodiments, the metal or metallic surface comprises Mo. In some embodiments, the metal or metallic surface comprises a conductive metal nitride. In some embodiments, the metal or metallic surface comprises a conductive metal boride. In some embodiments, the metal or metallic surface comprises a conductive metal carbide. In some embodiments, a metal or metallic surface comprises TiN. In some embodiments, a metal or metallic surface comprises TiC. In some embodiments, a metal or metallic surface comprises VN. In some embodiments, the first surface comprises a metal selected from a group consisting of Mo, W, Ru, Co, Cu, Ti and V. In some embodiments, the metal of the first surface is substantially completely in elemental form.

In some embodiments, a material comprising a transition metal is selectively deposited on a first Cu surface relative to a second SiOC surface. In some embodiments, a material comprising a transition metal is selectively deposited on a first Cu surface relative to a second silicon oxide surface. In some embodiments, the second SiOC or silicon oxide surface is passivated by a silylating agent.

### Second Surface

In some embodiments, the second surface is a dielectric surface. In some embodiments, the second surface is a low-k surface. In some embodiments, the second surface comprises an oxide. In some embodiments, the second surface comprises silicon. Examples of silicon-comprising dielectric materials include silicon oxide-based materials, including grown or deposited silicon dioxide, doped and/or porous oxides and native oxide on silicon. In some embodiments, the second surface comprises silicon oxide. In some embodiments, the second surface is a silicon oxide surface, such as a native oxide surface, a thermal oxide surface or a chemical oxide surface. In some embodiments, the second surface comprises carbon. In some embodiments, the second surface comprises silicon, oxygen and carbon. In some embodiments, the second surface comprises, consists essentially of, or consists of, SiOC. In some embodiments, the second surface is an etch-stop layer.

In some embodiments, the second surface comprises hydroxyl (—OH) groups. In some embodiments, the second surface may additionally comprise hydrogen (—H) terminations. The second surface may comprise passivation material, such as silylation. Thus, in some embodiments, the second surface is treated with a passivating agent before providing the transition metal precursor into the reaction chamber. The passivating agent may comprise a silylating agent. A silylating agent may be, for example, alyltrimethylsilane, chlorotrimethylsilane, N-(trimenthylsilyl)imidazole, octadecyltrichlorosilane, hexamethyldisilazane or N-(trimethylsilyl)dimethylamine.

In some embodiments the dielectric surface and metal or metallic surface are adjacent to each other.

The term dielectric is used in the description herein for the sake of simplicity in distinguishing from the other surface, namely the metal or metallic surface. It will be understood by those skilled in the art that not all non-conducting surfaces are dielectric surfaces. In some embodiments, selective deposition processes taught herein can deposit on metal or metallic surfaces with minimal deposition on non-conductive dielectric surfaces.

In some embodiments, the second surface may comprise a passivated silicon-based surface, for example a passivated SiOC. That is, in some embodiments, the second surface may comprise a low k surface comprising a passivation agent, such as a self-assembled monolayer.

In some embodiments, a substrate comprising a first metal surface and a second dielectric surface is provided. In some embodiments, a substrate comprising a first metallic surface and a second dielectric surface is provided. In some embodiments, the second surface may be a SiO₂-based surface. In some embodiments, the second surface may comprise Si—O bonds. In some embodiments, the second surface may comprise a SiO₂-based low-k material. In some embodiments, the second surface may comprise more than about 30%, or more than about 50% of SiO₂. In certain embodiments the second surface may comprise a silicon dioxide surface.

### Reaction Chamber

The method of depositing transition metal according to the current disclosure comprises providing a substrate in a reaction chamber. In other words, a substrate is brought into space where the deposition conditions can be controlled. The reaction chamber can form part of a vapor processing assembly for manufacturing semiconductor devices. The processing assembly may comprise one or more multi-station deposition chambers.

The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

### Cyclic Deposition Process

In the current disclosure, the deposition process may comprise a cyclic deposition process, such as an atomic layer deposition (ALD) process or a cyclic chemical vapor deposition (CVD) process. The term “cyclic deposition process” can refer to the sequential introduction of precursor(s) and/or reactant(s) into a reaction chamber to deposit material, such as transition metal, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

The process may comprise one or more cyclic phases. For example, pulsing of transition metal and second precursor may be repeated. In some embodiments, the process comprises or one or more acyclic phases. In some embodiments, the deposition process comprises the continuous flow of at least one precursor. In some embodiments, a transition metal precursor is continuously provided in the reaction chamber. In some embodiments, a second precursor is continuously provided in the reaction chamber. In such an embodiment, the process comprises a continuous flow of a precursor or a reactant. In some embodiments, one or more of the precursors and/or reactants are provided in the reaction chamber continuously.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a first precursor, such as a transition metal precursor, is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, a second precursor or a reactant may be introduced into the reaction chamber for use in converting the chemisorbed precursor to the desired material on the deposition surface. The second precursor or a reactant can be capable of further reaction with the first precursor. Purging steps may be utilized during one or more cycles, e.g., after each step of each cycle, to remove any excess precursor or reactant from the reaction chamber and/or to remove any reaction byproducts from the reaction chamber. Thus, in some embodiments, the cyclic deposition process comprises purging the reaction chamber after providing a transition metal precursor into the reaction chamber. In some embodiments, the cyclic deposition process comprises purging the reaction chamber after providing a second precursor into the reaction chamber. In some embodiments, the cyclic deposition process comprises purging the reaction chamber after providing a transition metal precursor into the reaction chamber, and after providing a second precursor into the reaction chamber. The reaction chamber may be purged after providing an optional third or further precursor into the reaction chamber.

CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

In some embodiments, at least one of a transition metal precursor and a second precursor is provided to the reaction chamber in pulses. In some embodiments, the transition metal precursor is supplied in pulses and the second precursor is supplied in pulses, and the reaction chamber is purged between consecutive pulses of a transition metal precursor and the second precursor. A duration of providing a transition metal precursor and/or a second precursor into the reaction chamber (i.e. first precursor pulse time and second precursor pulse time, respectively) may be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The duration of a transition metal precursor or a second precursor pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, transition metal precursor pulse time may be at least 5 seconds, or at least 10 seconds, or at least 20 seconds, or at least 30 seconds. In some embodiments, transition metal precursor pulse time may be at most 5 seconds, or at most 10 seconds or at most 20 seconds, or at most 40 seconds. In some embodiments, second precursor pulse time may be at least 5 seconds, or at least 10 seconds, or at least 20 seconds, or at least 30 seconds. In some embodiments, second precursor pulse time may be at most 5 seconds, or at most 10 seconds or at most 20 seconds, or at most 40 seconds.

The pulse times for transition metal precursor and for second precursor vary independently according to process in question. The selection of an appropriate pulse time may depend on the substrate topology. For higher aspect ratio structures, longer pulse times may be needed to obtain sufficient surface saturation in different areas of a high aspect ratio structure. Also the selected transition metal precursor and second precursor chemistries may influence suitable pulsing times. For process optimization purposes, shorter pulse times might be preferred as long as appropriate layer properties can be achieved. In some embodiments, transition metal precursor pulse time is longer tha second precursor pulse time. In some embodiments, second precursor pulse time is longer than transition metal precursor pulse time. In some embodiments, transition metal precursor pulse time is the same as second precursor pulse time.

In some embodiments, providing a transition metal precursor and/or a second precursor into the reaction chamber comprises pulsing the transition metal precursor and the second precursor over a substrate. In certain embodiments, pulse times in the range of several minutes may be used for the transition metal precursor and/or the second precursor. In some embodiments, transition metal precursor may be pulsed more than one time, for example two, three or four times, before a second precursor is pulsed to the reaction chamber. Similarly, there may be more than one pulse, such as two, three or four pulses, of a second precursor before transition metal precursor is pulsed (i.e. provided) into the reaction chamber.

A flow rate of the transition metal precursor and the second precursor (i.e. transition metal precursor flow rate and second precursor flow rate, respectively) may vary from about 5 sccm to about 20 slm. The flow rate of the different reaction gases may be selected independently for each gas. During providing a transition metal precursor and/or second precursor into the reaction chamber, a flow rate of the transition metal precursor and/or the second precursor may be less than 3,000 sccm, or less than 2,000 sccm, or less than 1,000 sccm, or less than 500 sccm, or less than 100 sccm. A transition metal precursor flow rate and/or a second precursor flow rate may be, for example, from 500 sccm to 1200 sccm, such as 600 sccm, 800 sccm or 1,000 sccm. In some embodiments, a flow rate of the transition metal precursor and/or the second precursor into the reaction chamber is between 50 sccm and 3,000 sccm, or between 50 sccm and 2,000 sccm, or between 50 sccm and 1,000 sccm. In some embodiments, a flow rate of the transition metal precursor and/or the second precursor into the reaction chamber is between 50 sccm and 900 sccm, or between 50 sccm and 800 sccm or between 50 sccm and 500 sccm. In some embodiments, higher flow rates may be utilized. For example, a transition metal precursor flow rate, a second precursor flow rate and/or an auxiliary reactant flow rate may be 5 slm or higher. In some embodiments, a transition metal precursor flow rate, a second precursor flow rate and/or auxiliary reactant flow rate may be 10 slm, 12 slm or 15 slm or 20 slm.

### Purging

As used herein, the term “purge” may refer to a procedure in which vapor phase precursors, reactants and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid, or at least reduce, gas-phase interactions between the two gases. It shall be understood that a purge can be effected either in time or in space, or both. For example in the case of temporal purges, purging can be used e.g. in the temporal sequence of providing a first precursor to a reactor chamber, providing a purge gas to the reactor chamber, and providing a second precursor to the reactor chamber, wherein the substrate on which a material is deposited does not move. For example in the case of spatial purges, purging can take the following form: moving a substrate from a first location to which a first precursor is supplied, through a purge gas curtain, to a second location to which a second precursor is supplied. Supplying of each precursor may be continuous or non-continuous. Purging times may be, for example, from about 0.01 seconds to about 20 seconds, from about 0.05 s to about 20 s, or from about 0.1 s to about 20 s, or from about 0.5 s to about 20 s, or from about 0.01 s to about 10 s, or from about 5 s to about 20 s, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor.

In some embodiments, the method comprises removing excess transition metal precursor from the reaction chamber by an inert gas prior to providing the second precursor in the reaction chamber. In some embodiments, the reaction chamber is purged between providing a transition metal precursor in a reaction chamber and providing a second precursor in the reaction chamber. In some embodiments, there is a purge step after every precursor and reactant pulse. Thus, the reaction chamber may be purged also between two pulses of the same chemistry, such as a transition metal precursor or a second precursor.

### Thermal Process

In some embodiments, the cyclic deposition process according to the current disclosure comprises a thermal deposition process. In thermal deposition, the chemical reactions are promoted by temperature regulation, such as increased temperature relevant to ambient temperature. Generally, temperature increase provides the energy needed for the formation of material comprising a transition metal in the absence of other external energy sources, such as plasma, radicals, or other forms of radiation. In some embodiments, the methods according to the current disclosure do not comprise plasma-enhanced phases. In some embodiments, the method according to the current disclosure is a plasma-enhanced deposition method, for example PEALD or PECVD.

In some embodiments, material comprising a transition metal may be deposited at a temperature from about 100° C. to about 500° C. For example, material comprising a transition metal may be deposited at a temperature from about 150° C. to about 500° C., or at a temperature from about 200° C. to about 500° C., or at a temperature from about 250° C. to about 500° C., or at a temperature from about 200° C. to about 400° C. In some embodiments of the current disclosure, material comprising a transition metal may be deposited at a temperature from about 150° C. to about 300° C., or at a temperature from about 200° C. to about 350° C. For example, transition metal nitride-comprising material may be deposited at a temperature of about 125° C. or about 175° C., or about 200° C., or about 225° C., or about 325° C. or about 375° C. or about 425° C. A temperature in a reaction chamber may be selected independently for different phases of the process. In some embodiments, the whole process is performed at a substantially constant temperature.

A pressure in a reaction chamber may be selected independently for different phases of the process. However, in some embodiments, the whole process is performed at a substantially constant pressure. In some embodiments, a first pressure may be used during transition metal precursor pulse, and a second pressure may be used during the second precursor pulse. A third or a further pressure may be used during purging or other process steps. In some embodiments, a pressure within the reaction chamber during the deposition process according to the current disclosure is less than 760 Ton, or a pressure within the reaction chamber during the deposition process is between 0.1 Torr and 760 Ton, or between 1 Torr and 100 Ton, or between 1 Torr and 10 Torr. In some embodiments, a pressure within the reaction chamber during the deposition process is less than about 0.001 Torr, less than 0.01 Torr, less than 0.1 Torr, less than 1 Torr, less than 10 Torr, less than 50 Torr, less than 100 Torr or less than 300 Torr. In some embodiments, a pressure within the reaction chamber during at least a part of the method according to the current disclosure is less than about 0.001 Torr, less than 0.01 Torr, less than 0.1 Torr, less than 1 Torr, less than 10 Torr or less than 50 Torr, less than 100 Torr or less than 300 Torr. For example, in some embodiments, a first pressure may be about 0.1 Torr, about 0.5 Torr, about 1 Torr, about 5 Torr, about 10 Torr, about 20 Torr or about 50 Torr. In some embodiments, a second pressure is about 0.1 Ton, about 0.5 Torr, about 1 Torr, about 5 Torr, about 10 Torr, about 20 Torr or about 50 Torr.

### Deposited Material

As used herein, the term “material comprising transition metal” may refer to a material comprising at least one transition metal. In some embodiments, the material comprises, consists essentially of, or consists of Mo. In some embodiments, the material comprises, consists essentially of, or consists of V. In some embodiments, the material comprises, consists essentially of, or consists of W. In some embodiments, the material comprises, consists essentially of, or consists of Cr. In some embodiments, the material comprises, consists essentially of, or consists of Nb. In some embodiments, the material comprises, consists essentially of, or consists of Ta. In some embodiments, the material comprises, consists essentially of, or consists of Ti. In some embodiments, the material comprises, consists essentially of, or consists of Zr. In some embodiments, the material comprises, consists essentially of, or consists of Hf. In some embodiments, the material comprises, consists essentially of, or consists of Sc. In some embodiments, the material comprises, consists essentially of, or consists of Y.

In some embodiments, the deposited material comprises, consists essentially of, or consists of molybdenum and cobalt. The composition of the material comprising transition metal may depend on the specific transition metal precursor and second precursor used in the process, as well as on the deposition temperature and the composition of the first surface of the substrate. In some embodiments, the material comprising transition metal contains at least 50 at. % transition metal. In some embodiments, the material comprising transition metal contains at least 70 at. % transition metal. In some embodiments, the material comprising transition metal contains at least 80 at. % transition metal. In some embodiments, the material comprising transition metal contains at least 90 at. % transition metal. In some embodiments, the material comprising transition metal contains at least 95 at. % transition metal. In some embodiments, the material comprising transition metal contains at least 98 at. % transition metal. The material comprising transition metal may consist essentially of, or consist of, transition metal. In some embodiments, a transition metal layer may consist essentially of, or consist of one or more transition metals. Material consisting of transition metal may include an acceptable amount of impurities, such as oxygen, carbon, chlorine or other halogen, and/or hydrogen that may originate from one or more precursors used to deposit the material comprising transition metal. In some embodiments, transition metal in the deposited material is at least partially in elemental form (i.e. has an oxidation state of 0). In some embodiments, transition metal in the deposited material is substantially completely, or completely, in elemental form.

Material comprising transition metal may comprise carbon. In some embodiments, the carbon content of material comprising transition metal is lower than about 40 at. %. In some embodiments, the carbon content of material comprising transition metal is lower than about 20 at. %. In some embodiments, the carbon content of material comprising transition metal is lower than about 15 at. %. In some embodiments, the carbon content of material comprising transition metal is lower than about 10 at. %. In some embodiments, transition metal in the deposited material is at least partially in carbidic form.

In some embodiments, material comprising transition metal comprises nitrogen. In some embodiments, the nitrogen content of material comprising transition metal is lower than about 40 at. %. In some embodiments, the nitrogen content of material comprising transition metal is lower than about 20 at. %. In some embodiments, the nitrogen content of material comprising transition metal is lower than about 15 at. %. In some embodiments, the nitrogen content of material comprising transition metal is lower than about 10 at. %. In some embodiments, transition metal in the deposited material is at least partially in nitride form. In some embodiments, material comprising transition metal comprises from about 60 to about 99 atomic percentage (at. %) transition metal and nitrogen, or about 75 to about 99 at. % transition metal and nitrogen, or about 75 to about 95 at. % transition metal and nitrogen, or about 75 to about 89 at. % transition metal and nitrogen. Material comprising transition metal deposited by a method according to the current disclosure may comprise, for example about 80 at. %, about 83 at. %, about 85 at. %, about 87 at. %, about 90 at. %, about 95 at. %, about 97 at. % or about 99 at. % transition metal and nitrogen.

In some embodiments, transition metal is deposited on a first surface of a substrate as a layer. In such embodiments, a transition metal layer is formed. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

Without limiting the current disclosure to any specific theory, in some embodiments it may be possible to produce transition metal layers with low resistivity. The resistivity of a transition metal layer according to the current disclosure may be lower than about 600 μΩ cm. In some embodiments, the resistivity of a transition metal layer is lower than about 500 μΩ cm, such as about 400 μΩ cm. In some embodiments, the resistivity of a transition metal layer is lower than about 300 μΩ cm, such as 250 μΩ cm. In some embodiments, the resistivity of a transition metal layer is lower than about 200 μΩ cm, such as about 170 μΩ cm. Especially, a molybdenum layer, i.e. layer according to the current disclosure comprising Mo, or comprising substantially only Mo, may have a resistivity below about 200 μΩ cm. In embodiments, in which the transition metal layer comprises a transition metal nitride, the resistivity may be higher than indicated above. The lowest resistivities are typically obtained for transition metal layers comprising elemental metal. For example, a transition metal layer may consist substantially of elemental transition metal, in which case the resistivity may be low.

A transition metal layer according to the current disclosure may consist essentially of, or consist of, one or more transition metals. Layer consisting of transition metal may include an acceptable amount of impurities, such as oxygen, carbon, chlorine or other halogen, and/or hydrogen that may originate from one or more precursors used to deposit the transition metal layer. In some embodiments, transition metal layer may contain substantially only transition metal and nitrogen, and substantially all the nitrogen is in nitride form. In some embodiments, the transition metal layer may be a seed layer. A seed layer may be used to enhance the deposition of another layer. In some embodiments, a transition metal layer is a barrier layer.

By way of example, a transition metal layer according to the current disclosure, such as a molybdenum layer comprising substantially only Mo, may be used as a seed layer before the deposition of a transition metal layer of similar or substantially same composition. Selective deposition processes disclosed herein may be used to selectively deposit a transition metal layer, such as a metallic molybdenum layer, on a metal surface as the first surface. The metal surface may be a copper surface. The metal surface may be a cobalt surface. In some embodiments, the metal surface is a capping layer overlying another layer, such as a metallic cobalt surface overlaying metallic copper. In some embodiments, the first metal surface, such as a copper or a cobalt surface, is positioned at a bottom of a feature. The feature may comprise side walls of an oxide material, such as silicon oxide or low k material, and a bottom comprising a cobalt surface. In such embodiments, the transition metal layer, such as a molybdenum layer, may be selectively deposited on the cobalt layer. The process may further comprise depositing additional transition metal, such as molybdenum, on the transition metal layer deposited according to the current disclosure. The additional transition metal may be deposited as known in the art. The deposition may be selective or non-selective. In some embodiments, the additional transition metal is molybdenum. In some embodiments, the additional transition metal is deposited using a thermal process. In some embodiments, the additional transition metal is deposited using a plasma-assisted process. In some embodiments, the additional transition metal is molybdenum and the molybdenum precursor used for depositing the additional layer is a metal halide or a metal oxyhalide precursor, such as MoCl₅ or MoO₂Cl₂. In some embodiments, the feature is filled with the additional transition metal material. In some embodiments, high-conductivity metallic molybdenum is deposited in the feature.

Thus, the selectively deposited molybdenum layer may be a molybdenum seed layer. In some embodiments, the selectively deposited molybdenum seed layer may be used to protect the underlying metal layer from damage. For example, in embodiments, in which the transition metal is deposited on metallic copper, or on a metallic cobalt layer overlying a copper material, a halide-based metal precursor may etch the copper material. Depositing a seed layer according to the current disclosure may reduce or avoid the etching. The method in which the transition metal material according to the current disclosure is used as a seed layer may be used, for example, in back-end-of-line applications in filling vias, via fill in metal gate and in source-drain metal contact.

Particularly, in metal gate applications, metallic molybdenum may be deposited in features comprising a bottom having multiple metal or metallic materials, such as TiN, MoN, TiC and/or W. Some materials, such as TiN and TiC may be etched by a halide-based molybdenum precursors, releasing TiCl₄. This issue may be mitigated or avoided by using a seed layer (also called a liner) according to the current disclosure.

In some embodiments, the first surface may comprise phosphorus-doped silicon or boron-doped silicon germanium inside a feature, and the second surface may be a low k material, such as SiON forming side walls of the feature. Metallic molybdenum deposited using an aromatic molybdenum precursor, such as bis(ethylbenzene)molybdenum may provide a high-quality interface between metal and the underlying surface, and metallic molybdenum deposited by alternative methods can be used to fill up the feature.

In some embodiments, the transition metal layer may comprise less than about 30 at. %, or less than about 20 at. %, less than about 10 at. %, less than about 8 at. %, less than about 7 at. %, less than about 5 at. %, or less than about 2 at. % oxygen. In some embodiments, the transition metal layer may comprise less than about 20 at. %, less than about 15 at. %, less than about 10 at. %, less than about 8 at. %, less than about 5 at. % or less than about 3 at. % carbon.

In the method according to the current disclosure, a transition metal precursor is provided into the reaction chamber in a vapor phase, and a second precursor is provided into the reaction chamber in a vapor phase to form material comprising a transition metal on the substrate.

The transition metal precursor may be in vapor phase when it is in a reaction chamber. The transition metal precursor may be partially gaseous or liquid, or even solid at some points in time prior to being provided into the reaction chamber. In other words, a transition metal precursor may be solid, liquid or gaseous, for example, in a precursor vessel or other receptacle before delivery into a reaction chamber. Various means of bringing the transition metal precursor into gas phase can be applied when it is delivered into the reaction chamber. Such means may include, for example, heaters, vaporizers, gas flow or applying lowered pressure, or any combination thereof. Thus, the method according to the current disclosure may comprise heating the transition metal precursor prior to providing it to the reaction chamber. In some embodiments, transition metal precursor is heated to at least 60° C., to at least 100° C., or to at least 110° C., or to at least 120° C. or to at least 130° C. or to at least 140° C. in the vessel. In some embodiments, the transition metal precursor is heated to at most 160° C., or to at most 140° C., or to at most 120° C., or to at most 100° C., or to at most 80° C., or to at most 60° C. Also a precursor injector system may be heated to improve the vapor phase delivery of the transition metal precursor to the reaction chamber. The temperature of the precursor injector system is selected to keep the transition metal precursor in vapor phase. The temperature of the precursor injector system may be lower, higher or the same as the temperature of the vessel holding the transition metal precursor.

In this disclosure, “gas” can include material that is a gas at normal temperature and pressure (NTP), a vaporized solid and/or a vaporized liquid, and can be constituted by a single gas or a mixture of gases, depending on the context. Transition metal precursor may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

### Transition Metal Precursor

In the method according to the current disclosure, the transition metal precursor comprises a transition metal from any of groups 3 to 6 of the periodic table of elements.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may me an element or a compound that is not incorporated into the resulting compound or element to a significant extent. However, a reactant may also contribute to the resulting compound or element in certain embodiments.

As used herein, “a transition metal precursor” includes a gas or a material that can become gaseous and that can be represented by a chemical formula that includes transition metal selected from groups 3 (Sc, Y, La), 4 (titanium, zirconium, hafnium), 5 (vanadium, niobium, tantalum) or 6 (chromium, molybdenum and tungsten) of the periodic table of elements. In some embodiments, the transition metal is in a low oxidation state relative to the highest stable oxidation state possible for that transition metal. In some embodiments, the oxidation state of the transition metal is 3+. In some embodiments, the oxidation state of the transition metal is 2+. In some embodiments, the oxidation state of the transition metal is zero. Particularly, in a transition metal precursor comprising an arene ligand, the oxidation state of the transition metal may be 0. In a transition metal precursor comprising a cyclopentadienyl ligand, the oxidation state of the transition metal may be higher than 0. For group 5+4 oxidation state is relevant. For Cp, higher oxidation state metals are ok. Write about Cp+higher oxidation state metals

In some embodiments, the transition metal precursor comprises a group 3 transition metal. The transition metal precursor may thus comprise scandium (Sc). The transition metal precursor may alternatively comprise yttrium (Y). The transition metal precursor may alternatively comprise lanthanum (La). In some embodiments, the transition metal in the transition metal precursor is selected from a group consisting of Y and Sc.

In some embodiments, the transition metal precursor comprises a group 4 transition metal. The transition metal precursor may thus comprise titanium (Ti). The transition metal precursor may alternatively comprise zirconium (Zr). As another alternative, the transition metal precursor may comprise hafnium (Hf). In some embodiments, the transition metal in the transition metal precursor is selected from a group consisting of Ti, Zr and Hf. In some embodiments, the transition metal in the transition metal precursor is selected from a group consisting of Ti and Hf.

In some embodiments, the transition metal precursor comprises a group 5 transition metal. The transition metal precursor may thus comprise vanadium (V), or the transition metal precursor may comprise niobium (Nb), or the transition metal precursor may comprise tantalum (Ta). In some embodiments, the transition metal in the transition metal precursor is selected from a group consisting of vanadium, niobium and tantalum. In some embodiments, the transition metal in the transition metal precursor is selected from a group consisting of V and Ta.

In some embodiments, the transition metal precursor comprises a group 6 transition metal. The transition metal precursor may comprise chromium (Cr). The transition metal precursor may comprise molybdenum (Mo). In some embodiments, the group 6 transition metal in the transition metal precursor is molybdenum. The transition metal precursor may comprise tungsten (W). In some embodiments, the transition metal in the transition metal precursor is selected from a group consisting of Cr, Mo and W. In some embodiments, the transition metal in the transition metal precursor is selected from a group consisting of Mo and W.

In some embodiments, transition metal precursor is provided in a mixture of two or more compounds. In a mixture, the other compounds in addition to the transition metal precursor may be inert compounds or elements. In some embodiments, transition metal precursor is provided in a composition. Compositions suitable for use as composition can include a transition metal compound and an effective amount of one or more stabilizing agents. Composition may be a solution or a gas in standard conditions.

In the embodiments of the current disclosure, a transition metal precursor comprises a transition metal atom and an aromatic ligand. In some embodiments, transition metal precursor comprises an organometallic compound comprising a transition metal according to the current disclosure. Thus, the transition metal precursor is an aromatic organometallic precursor. By an organometallic precursor is herein meant a transition metal precursor comprising a transition metal, such as a group 3 to 6 transition metal according to the current disclosure, and an organic ligand, wherein the transition metal atom is directly bonded to a carbon atom. In embodiments in which an organometallic precursor comprises two or more transition metal atoms, all of the metal atoms are directly bonded with a carbon atom.

In some embodiments, the transition metal precursor comprises only a transition metal atom according to the current disclosure, carbon (C) and hydrogen (H). In other words, transition metal precursor does not contain oxygen, nitrogen or other additional elements. In some embodiments, the transition metal precursor comprises only transition metal, C and H. In some embodiments, the transition metal precursor comprises only Sc, C and H. In some embodiments, the transition metal precursor comprises only Y, C and H. In some embodiments, the transition metal precursor comprises only Hf, C and H. In some embodiments, the transition metal precursor comprises only Zr, C and H. In some embodiments, the transition metal precursor comprises only Ti, C and H. In some embodiments, the transition metal precursor comprises only Cr, C and H. In some embodiments, the transition metal precursor comprises only Mo, C and H. In some embodiments, the transition metal precursor comprises only W, C and H. In some embodiments, the transition metal precursor comprises only V, C and H.

However, in some embodiments, the metal-organic or organometallic precursor comprises a transition metal according to the current disclosure, C, H and at least one additional element. The additional element may be, for example, oxygen, nitrogen or a halogen. In some embodiments, the additional element is not directly bonded to the metal. Thus, in some embodiments, a transition metal precursor does not contain a metal-nitrogen bond. In some embodiments, a transition metal precursor does not contain a metal-oxygen bond. In some embodiments, a transition metal precursor does not contain a metal-halogen bond. The at least one additional element in a metal-organic or organometallic precursor may be a ligand. The at least one additional element may thus be an additional ligand. In some embodiments, the metal-organic or organometallic precursor comprises an additional ligand, and the ligand is a halide. In some embodiments, the metal-organic or organometallic precursor may comprise at least two additional ligands, and one or two of the additional ligands may be a halide. Each of the additional ligands may be independently selected. A halide may be selected from the group consisting of chloro, bromo and iodo. Thus, a ligand may be a halogen atom, selected from the group consisting of chlorine, bromine and iodine.

In some embodiments, the transition metal precursor comprises an alkene ligand. The alkene may be a cyclic alkene. In some embodiments, the transition metal precursor comprises a pi-arene ligand. In some embodiments, the transition metal precursor comprises an alkene or an arene ligand and an additional ligand.

In some embodiments, transition metal precursor comprises at least two organic ligands. In some embodiments, transition metal precursor comprises at least three organic ligands. In some embodiments, transition metal precursor comprises four organic ligands. In some embodiments, transition metal precursor comprises an organic ligand and a hydride ligand. In some embodiments, transition metal precursor comprises an organic ligand and two or more hydride ligands. In some embodiments, transition metal precursor comprises two organic ligands and two hydride ligands. In some embodiments, one or more of the organic ligands is a hydrocarbon ligand.

The transition metal precursor may comprise a benzene or a cyclopentadienyl ring. In some embodiments, the transition metal precursor comprises a benzene or a cyclopentadienyl ring. The transition metal precursor may comprise one or more benzene rings. In some embodiments, the transition metal precursor comprises two benzene rings. One or both benzene rings may comprise hydrocarbon substituents. In some embodiments, each benzene ring of the transition metal precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec-form of a butyl, pentyl or hexyl moiety. Add η⁶-coordination mode. In some embodiments, the transition metal precursor comprises, consist essentially of, or consist of bis(ethylbenzene)transition metal. In some embodiments, a transition metal precursor comprises, consist essentially of, or consist of, V(Bz)₂, MoBz₂, CrBz₂, WBz₂, ScBz₂, YBz₂, HfBz₂, ZrBz₂, TiBz₂, V(EtBz)₂, Mo(EtBz)₂, Cr(EtBz)₂, Sc(EtBz)₂, Y(EtBz)₂, Hf(EtBz)₂, Zr(EtBz)₂, Ti(EtBz)₂, or W(EtBz)₂, wherein Bz stands for benzene and Et for ethyl. In some embodiments, the transition metal precursor comprises two alkyl-substituted benzene rings.

In some embodiments, the transition metal precursor comprises bis(ethylbenzene)molybdenum. In some embodiments, the transition metal precursor consists essentially of, or consists of bis(ethylbenzene)molybdenum

The transition metal precursor may comprise one or more cyclopentadienyl groups. In some embodiments, the transition metal precursor comprises two cyclopentadienyl groups. A cyclopentadienyl group may be similarly substituted as a benzene group. In other words, one or more of the cyclopentadienyl groups may comprise hydrocarbon substituents. In some embodiments, one or both of the cyclopentadienyl groups has an alkyl substituent, such as a methyl group, an ethyl group, or a linear or branched alkyl group comprising three, four, five or six carbon atoms. For example, the alkyl substituent of the cyclopentadienyl group may be an n-propyl group, an iso-propyl group. Further, the alkyl substituent may be an n-, iso-, tert-or sec-form of a butyl, pentyl or hexyl moiety.

Some examples of transition metal precursors according to the current disclosure comprising a cyclopentadienyl moiety are TiCp₂Cl₂, TiCp₂Br₂, TiCp₂, TiCp₂(CO)₂, TiCp₂I₂, TiCp₂H₂, TiCpCl₃, TiCpBr₃, TiCpI₃, HfCp₂Cl₂, HfCp₂Br₂, HfCp₂, HfCp₂(CO)₂, HfCp₂I₂, HfCp₂H₂, HfCpCl₃, HfCpBr₃, HfCpI₃, ZrCp₂Cl₂, ZrCp₂Br₂, ZrCp₂, ZrCp₂(CO)₂, ZrCp₂I₂, ZrCp₂H₂, ZrCpCl₃, ZrCpBr₃, ZrCpI₃, VCp₂Cl₂, VCp₂Br₂, VCp₂I₂, VCp₂, VCp₂(CO)₄, TaCp₂Cl₂, TaCp₂I₂, TaCp₂Br₂, TaCp₂H₂, NbCp₂, NbCp₂H₂, NbCp₂Cl₂, MoCp₂Cl₂, MoCp₂H₂, CrCp₂H₂, CrCp₂, CrCp₂Cl₂, WCp₂H₂, WCp₂Cl₂, WCp₂Br₂ and WCp₂I₂.

Some further examples of cyclopentadienyl-comprising transition metal precursors are Ti(iPrCp)₂Cl₂, Ti(iPrCp)₂, Ti(MeCp)₂Cl₂, Ti(MeCp)₂, Ti(EtCp)₂Cl₂, Ti(EtCp)₂, Hf(iPrCp)₂Cl₂, Hf(iPrCp)₂, Hf(MeCp)₂Cl₂, Hf(MeCp)₂, Hf(EtCp)₂Cl₂, Hf(EtCp)₂, Zr(iPrCp)₂Cl₂, Zr(iPrCp)₂, Zr(MeCp)₂Cl₂, Zr(MeCp)₂, Zr(EtCp)₂Cl₂, Zr(EtCp)₂, V(iPrCp)₂Cl₂, V(iPrCp)₂, V(MeCp)₂Cl₂, V(MeCp)₂, V(EtCp)₂Cl₂, V(EtCp)₂, Mo(iPrCp)₂Cl₂, Mo(iPrCp)₂H₂, Mo(EtCp)₂H₂, Cr(MeCp)₂, Cr(EtCp)₂, Cr(iPrCp)₂, Cr(tBuCp)₂, Cr(nBuCp)₂, Cr(MesCp)₂, Cr(Me₄Cp)₂, W(EtCp)₂H₂, W(iPrCp)₂Cl₂ and W(iPrCp)₂H₂. In the formulas, Cp stands for cyclopentadienyl, iPr stands for isopropyl, Me stands for methyl, Et stands for ethyl, iPr stands for iso-propyl, tBu stands for tert-butyl and nBu stands for n-butyl.

In some embodiments, the transition metal precursor may comprise a carbonyl group-comprising ligand. For example, the transition metal precursor may comprise, consist essentially of, or consist of Mo(CO)₆, Mo(1,3,5-cycloheptatriene)(CO)₃. Additionally, in some embodiments, the transition metal precursor comprises a nitrosyl group-comprising ligand. For example, the transition metal precursor may comprise, consist essentially of, or consist of MoCp(CO)₂(NO).

### Second Precursor

In the method according to the current disclosure, a second precursor is provided into the reaction chamber. In other words, a second precursor is contacted with the substrate comprising a chemisorbed transition metal precursor. The conversion of a transition metal precursor to transition metal may take place at the substrate surface. In some embodiments, the conversion may take place at least partially in the gas phase. The term second precursor can refer to a gas or a material that can become gaseous and that is capable of reacting with the transition metal precursor to deposit desired material comprising a transition metal on the first surface of the substrate. In some embodiments, the second precursor comprises a group 14 element selected from carbon (C), silicon (Si), germanium (Ge) or tin (Sn).

In some embodiments, the second precursor comprises a reducing agent. In some embodiments, the reducing agent comprises molecular hydrogen (H₂). In some embodiments, the reducing agent is molecular hydrogen (H₂).

In some embodiments, the second precursor comprises a silane, such as an alkylsilane. In some embodiments, the silane is a disilane. In some embodiments, the silane comprises hexamethyl disilane.

In some embodiments, the second precursor comprises a carboxyl group. In some embodiments, the second precursor comprises a carboxylic acid. A carboxyl group-comprising second precursor may be a C1 to C7 carboxylic acid, or a C1 to C3 carboxylic acid. Exemplary carboxylic acids according to the current disclosure are formic acid, acetic acid, propionic acid, butyric acid, pentanoic acid, hexanoic acid, heptanoic acid, isobutyric acid, 2-methylbutanoic acid, 3-methylbutanoic acid, pivalic acid, 2,2-dimethylbutanoic acid, 2-methylpentanoic acid, 3-methylpentanoic acid, 2-ethylbutanoic acid, 2-ethylpentanoic acid and 2,3-dimethylbutanoic acid. When a carboxylic acid-comprising second precursor is used, the carbon content of the deposited material comprising a transition metal may be higher than when alternative second precursors are used. However, for certain applications, this may be acceptable, or even advantageous. Further, adding further reactants into the deposition process, it may be possible to regulate the carbon content of the deposited material.

In some embodiments, the second precursor comprises a halogen. In some embodiments, the halogen is selected from a group consisting of iodine and bromine. In some embodiments, the second precursor comprises a group 14 element. In some embodiments, the second precursor comprises a group 14 element and a halogen.

Without limiting the current disclosure to any specific theory, the second precursor may form two monoanionic species, both attaching to a transition metal precursor chemisorbed to the substrate. This may change the formal oxidation state of the transition metal, and lead into release of one or more of the groups attached to it. The release may take place through intermediate steps. In some embodiments, the bond that may be broken is a bond between a group 14 element and a halogen. In some embodiments, the bond that may be broken is a carbon-halogen bond. In some embodiments, the bond that may be broken is a bond between two halogen atoms. The halogen may be the same or a different element. In some embodiments, the bond that may be broken is a bond between two atoms of a group 14 element. The group 14 element may be the same or a different element. For example, the bond that may be broken may be a C—Br bond, or a C—I bond, or a Br—Br bond, or a I—I bond, or a C—Si bond, or a C—Ge bond, or a Si—Si bond, or a Ge—Ge bond.

In some embodiments, the second precursor comprises a halogenated hydrocarbon. In some embodiments, the halogenated hydrocarbon comprises two or more halogen atoms selected from iodine and bromine. In some embodiments, the at least two halogen atoms are attached to different carbon atoms. In some embodiments, two of the halogen atoms in the halogenated hydrocarbon are attached to adjacent carbon atoms of a carbon chain. In some embodiments, the halogenated hydrocarbon is a 1,2-dihaloalkane or 1,2-dihaloalkene or 1,2-dihaloalkyne or 1,2-dihaloarene. In some embodiments, the two halogen atoms of the halogenated hydrocarbon are the same halogen. In some embodiments, the halogenated hydrocarbon is 1,2-diiodoethane.

In some embodiments, the second precursor comprises a halogenated aromatic hydrocarbon. For example, the second precursor comprises, consists essentially of, or consists of iodobenzene or 1-iodobutane. In some embodiments, the second precursor comprises, consists essentially of, or consists of bromobenzene or 1-bromobutane.

In some embodiments, the second precursor comprises a group 14 element selected from silicon (Si), germanium (Ge) or tin (Sn). In some embodiments, the second precursor comprises a group 14 element selected from a group consisting of Si and Ge. In some embodiments, the second precursor comprises a group 14 element selected from a group consisting of Si and Sn. In some embodiments, the second precursor comprises a group 14 element selected from a group consisting of Ge and Sn.

In some embodiments, a second precursor comprises one atom of a group 14 element according to the current disclosure. In some embodiments, a second precursor comprises two atoms of a group 14 element according to the current disclosure. The two or more atoms of group 14 element may be the same or a different element. For example, the second precursor may contain two C atoms, two Si atoms, two Ge atoms or two Sn atoms. Alternatively, the second precursor may comprise a C atom and a Si atom, a C atom and a Ge atom, a C atom and a Sn atom, a Si atom and a Ge atom, a Si atom and a Sn atom or a Sn atom and a Ge atom. In some embodiments, a second precursor comprises two atoms of a group 14 element according to the current disclosure bonded to each other.

In some embodiments, a second precursor comprises two atoms of a group 14 element according to the current disclosure bonded to each other, and each atom of the group 14 element has a halogen atom attached to it. The halogen may be, for example, Cl, F or I. In some embodiments, a second precursor comprises two atoms of a group 14 element according to the current disclosure bonded to each other, and each atom of the group 14 element has an alkyl group attached to it. For example, the alkyl group may be a methyl, ethyl, propyl, butyl or pentyl.

In some embodiments, a second precursor comprises at least one C—C bond. In some embodiments, a second precursor comprises at least one Si—Si bond. In some embodiments, a second precursor comprises at least one Ge—Ge bond. In some embodiments, a second precursor comprises at least one Sn—Sn bond. In some embodiments, a second precursor comprises at least one C—C bond with a halogen atom attached to each C atom. In some embodiments, a second precursor comprises at least one Si—Si bond with a halogen atom attached to each Si atom. In some embodiments, a second precursor comprises at least one Ge—Ge bond with a halogen atom attached to each Ge atom. In some embodiments, a second precursor comprises at least one Sn—Sn bond with a halogen atom attached to each Ge atom. In some embodiments, the second precursor comprises one bond between group 14 elements with a halogen atom attached to each group 14 element atom.

In some embodiments, the second precursor comprises an organic group in addition to the group 14 element. An organic group is a group comprising a carbon-hydrogen bond. Thus, the second precursor comprises a group 14 element selected from a group consisting of Si, Ge and Sn, and an organic group. The second precursor may comprise a hydrocarbon comprising at least one carbon atom. There may be one, two, three or four organic groups in a second precursor. Each organic group may independently contain 1 to 12 carbon atoms. For example, each organic group may independently comprise a C1 to C4 group (i.e. contain from one to four carbon atoms), a C1 to C6 group, a C1 to C8 group, a C1-C10 group, a C2 to C12 group, a C2 to C6 group, a C2 to C6 group, or a C4 to C8 group or a C4 to C10 group. Therefore, each organic group may independently comprise a C1, C2, C3, C4, C5, C6, C7, C8 or a C10 group. An organic group may comprise an alkyl or an aryl. An organic group may comprise on or more linear, branched or cyclic alkyl. In some embodiments, an organic group comprises an aryl group. An alkyl or an aryl group may be substituted with one or more functional groups, such as a halogen, alcohol, amine or benzene.

For example, the organic group may comprise a halogenated methane, ethane, propane, 2-methylpropane, 2,2-dimethylpropane (neopentane), n-butane, 2-methylbutane, 2,2-dimethylbutane, n-pentane, 2-methylpantane, 3-methylpentane or an n-hexane. In some embodiments, the second precursor comprises two halogen atoms. In some further embodiments, the at least two halogen atoms of the second precursor may be attached to different carbon atoms. The halogen atoms may be the same halogen, for example bromine, iodine, fluorine or chlorine. Alternatively, the halogens may be different halogens, such as iodine and bromine, bromine and chlorine, chlorine and iodine. In some embodiments, the second precursor comprises 1,2-dihaloalkane or 1,2-dihaloalkene or 1,2-dihaloalkyne or 1,2-dihaloarene, where the halogens are attached to adjacent carbon atoms.

In some embodiments, a second precursor has a general Formula (I) RₐMX_{b} or R_{c}X_{d}M-MR_{c}X_{d}. In Formula (I), a is 0, 1, 2 or 3, b is 4-a, c is 0, 1 or 2, d is 3-c, R is an organic group as described above, M is Si, Ge or Sn, and each X is independently any ligand. R may be a hydrocarbon. If a is two or three, or c is two, each R is selected independently. In some embodiments, each R is selected from alkyls and aryls. In some embodiments, R is an organic group as described above. In some embodiments, R is alkyl or an aryl. For clarity, X may represent different ligands in one second precursor species. Thus, in some embodiments, a second precursor may be, for example CH₂Br₂, CH₂I₂ or CH₂Cl₂, SiH₂Br₂, SiH₂I₂ or SiH₂Cl₂.

In some embodiments, X is hydrogen, a substituted or an unsubstituted alkyl or aryl or a halogen. In some embodiments, X is H. In some embodiments, X is an alkyl or an aryl. In some embodiments, X is a C1 to C4 alkyl. In some embodiments, X is a substituted alkyl or aryl. In some embodiments, X is a substituted alkyl or aryl, wherein the substituent is same as M. In some embodiments, X is selected from a group consisting of H, Me, Et, nPr, iPr, nBu, tBu, M′Me₃, M′Et₃, M′Pr₃, M′Bu₃, Cl, Br, or I, wherein M′ is same as M.

In some embodiments, a second precursor has a more specific Formula (II) RₐCX_{b}. More specifically, a second precursor may have a formula R₃CX, R₂CX₂, RCX₃, or CX₄. In Formula (II), a, b, R and X are as in Formula (I). However, in some embodiments, a carbon atom does not comprise four identical substituents. In some embodiments, the second precursor is not CH₄. In some embodiments, the second precursor is not CH₂Me₂. In some embodiments, a second precursor is not CH₂Et₂. In some embodiments, second precursor is not C₂H₂. In some embodiments, second precursor is not H₃C—CHI₂.

In some embodiments, a second precursor has a more specific Formula (III) RₐSiX_{b}. More specifically, a second precursor may have a formula R₃SiX, R₂SiX₂, RSiX₃, or SiX₄. In Formula (III), a, b, R and X are as in Formula (I). However, in some embodiments, a silicon atom does not comprise four identical substituents. In some embodiments, the second precursor is not SiH₄. In some embodiments, the second precursor is not SiH₂Me₂. In some embodiments, a second precursor is not SiH₂Et₂. In some embodiments, second precursor is not Si₂H₂.

In some embodiments, a second precursor has a more specific Formula (IV) RₐGeX_{b}. More specifically, a second precursor may have a formula R₃GeX, R₂GeX₂, RGeX₃, or GeX₄. In Formula (IV), a, b, R and X are as in Formula (I). However, in some embodiments, a Ge atom does not comprise four identical substituents. In some embodiments, the second precursor is not GeH₄. In some embodiments, the second precursor is not GeH₂Me₂. In some embodiments, a second precursor is not GeH₂Et₂. In some embodiments, second precursor is not Ge₂H₂.

In some embodiments, a second precursor has a more specific Formula (V) RₐSnX_{b}. More specifically, a second precursor may have a formula R₃SnX, R₂SnX₂, RSnX₃, or SnX₄. In Formula (V), a, b, R and X are as in Formula (I). However, in some embodiments, a tin atom does not comprise four identical substituents. In some embodiments, the second precursor is not SnH₄. In some embodiments, the second precursor is not SnH₂Me₂. In some embodiments, a second precursor is not SnH₂Et₂. In some embodiments, second precursor is not Sn₂H₂.

In some embodiments, the second precursor comprises a halogen selected from iodine and bromine. In some embodiments, the second precursor comprises an alkyl halide. In some embodiments, the second precursor comprises an alkyl bromide. In some embodiments the second precursor comprises an alkyl iodide. In some embodiments the second precursor comprises an aryl halide. In some embodiments the second precursor comprises an aryl bromide. In some embodiments the second precursor comprises an aryl iodide. In some embodiments the second precursor comprises an acyl halide. In some embodiments the second precursor comprises an acyl bromide. In some embodiments the second precursor comprises an acyl iodide. In some embodiments, the second precursor comprises, consists essentially of, or consists of molecular halogen. In some embodiments, the second precursor comprises molecular iodine, I₂. In some embodiments, the second precursor comprises molecular bromine, Br₂. In some embodiments, the second precursor comprises a compound comprising a silicon to halogen bond. In some embodiments, the second precursor comprises a compound comprising a silicon to bromine bond. In some embodiments, the second precursor comprises a compound comprising a silicon to iodine bond.

In some embodiments, the second precursor comprises a halogenated organic compound (organohalide), and the halogen is selected from a group consisting of bromine and iodine. In some embodiments, an organohalide comprising bromine and/or iodine does not comprise a group 14 element. Some second precursors may comprise both one or more group 14 element selected from Si, Ge and Sn and an organohalide group, wherein the halogen is selected from bromine and iodine.

In some embodiments, the organohalide in the second precursor comprises two or more halogen atoms. The second precursor may or may not comprise a group 14 element. Thus, in some embodiments, a second precursor consists of carbon, hydrogen and one or more halogen atoms selected from I and Br. In some embodiments, a second precursor consists of carbon, oxygen, hydrogen and one or more halogen atoms selected from I and Br.

In some embodiments, a second precursor comprises a hydrocarbon that contains one bromine or one iodine atom. In some embodiments, a second precursor comprises a hydrocarbon that contains at least one halogen atom, each halogen selected independently of bromine and iodine. In some embodiments, a second precursor comprises a hydrocarbon that contains two or more bromine or iodine atoms. In some embodiments, a second precursor comprises a hydrocarbon where two or more bromine or iodine atoms are bonded to a single carbon atom. In some embodiments the second precursor comprises a hydrocarbon that contains two or more halogen atoms, the halogen atoms being selected from bromine and iodine. In some embodiments the second precursor comprises a hydrocarbon where two or more bromine or iodine atoms are bonded to a single carbon atom. In some embodiments, the second precursor comprises a hydrocarbon in which two or more bromine or iodine atoms are bonded to different carbon atoms. In some embodiments, at least two halogen atoms in the second precursor are attached to adjacent carbon atoms of the hydrocarbon. In some embodiments, said carbon atoms are non-adjacent, i.e. the carbon atoms are not directly bonded to each other. In some embodiments, the second precursor comprises a 1,2-dihaloalkane or 1,2-dihaloalkene or 1,2-dihaloalkyne or 1,2-dihaloarene. In some embodiments, the halogen atoms of the second precursor are the same halogen. In some embodiments, two halogen atoms of the second precursor are iodine. In some embodiments, the two halogen atoms of the second precursor are bromine. In some embodiments, the second precursor comprises 1,2-diiodoethane. In some embodiments, the second precursor consists essentially of, or consists of 1,2-diiodoethane.

In some embodiments, the second precursor has a general Formula (VI) XₐR_{b}C—(CX_{c}R“_{d})ₙ—CXₐR′_{b}, wherein X is halogen, R, R′ and R” are independently H or an alkyl group, a and b are independently 1 or 2, so that for each carbon atom a+b=3, n is 0, 1, 2, 3, 4 or 5, and c and d are independently 0, 1 or 2, so that for each carbon atom c+d=2.

In some embodiments, the second precursor has a general Formula (VII) XₐR_{b}C—CXₐR′_{b}, wherein X is halogen, R and R′ are independently H or an alkyl group, a and b are independently 1 or 2, so that for each carbon atom a+b=3.

In some embodiments, the second precursor is a nitrogen precursor. However, in some embodiments, the second precursor may be, for example, a reducing agent, and a transition metal and nitrogen-comprising material, such as transition metal nitride, is formed through converting another transition metal-comprising material, such as metallic transition metal, into a transition metal and nitrogen-comprising material. In such embodiments, a three-phase process may be utilized, in which transition metal precursor and a second precursor are provided into the reaction chamber before providing a nitrogen precursor into the reaction chamber. Each of the transition metal precursor and the second precursor may be provided into the reaction chamber once, or multiple times before providing the nitrogen precursor into the reaction chamber.

The term nitrogen precursor can refer to a gas or a material that can become gaseous and that can be represented by a chemical formula that includes nitrogen. In some cases, the chemical formula includes nitrogen and hydrogen. In some cases, the nitrogen precursor does not include diatomic nitrogen.

The nitrogen precursor may be selected from one or more of molecular nitrogen (N₂), ammonia (NH₃), hydrazine (NH₂NH₂), a hydrazine derivative, a nitrogen-based plasma and other compounds comprising or consisting of nitrogen and hydrogen, such as a mixture of gaseous H₂ and N₂.

In some embodiments, the nitrogen precursor comprises hydrazine. In some embodiments, the nitrogen precursor consists essentially of, or consists of hydrazine. In some embodiments the nitrogen precursor comprises hydrazine substituted by one or more alkyl or aryl substituents. In some embodiments the nitrogen precursor consists essentially of, or consists of hydrazine substituted by one or more alkyl or aryl substituents. In some embodiments, the hydrazine derivative comprises an alkyl-hydrazine including at least one of: tertbutylhydrazine (C₄H₉N₂H₃), methylhydrazine (CH₃NHNH₂), 1,1-dimethylhydrazine ((CH₃)₂NNH₂), 1,2-dimethylhydrazine (CH₃)NHNH(CH₃), ethylhydrazine, 1,1-diethylhydrazine, 1-ethyl-1-methylhydrazine, isopropylhydrazine, tert-butyl-hydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, or azo-tert-butane.

In some embodiments, the nitrogen precursor comprises a plasma, such as NH₃ plasma, N₂ plasma and/or N₂/H₂ plasma. In some embodiments, the nitrogen-based plasma may be generated by the application of RF power to a nitrogen comprising gas and the nitrogen-based plasma may comprise atomic nitrogen (N), nitrogen ions, nitrogen radicals, and excited species of nitrogen. In some embodiments, the nitrogen-based plasma may further comprise additional reactive species, such as, by the addition of a further gas.

In some embodiments, the nitrogen precursor comprises only nitrogen and hydrogen. For example, a mixture of nitrogen gas and hydrogen gas may be used. In some embodiments, the nitrogen precursor is a mixture of gaseous H₂ and N₂. In some embodiments, the nitrogen precursor is selected from a group consisting of NH₃, NH₂NH₂, and mixture of gaseous H₂ and N₂. In some embodiments, the nitrogen precursor does not include diatomic nitrogen, i.e. the nitrogen precursor is a non-diatomic precursor. In some embodiments, the nitrogen precursor comprises ammonia. In some embodiments, the nitrogen precursor consists essentially of, or consists of ammonia. In some embodiments the nitrogen precursor comprises an alkylamine. In some embodiments the nitrogen precursor consists essentially of or consists of an alkylamine. Examples of alkylamines include dimethylamine, n-butylamine and t-butylamine.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

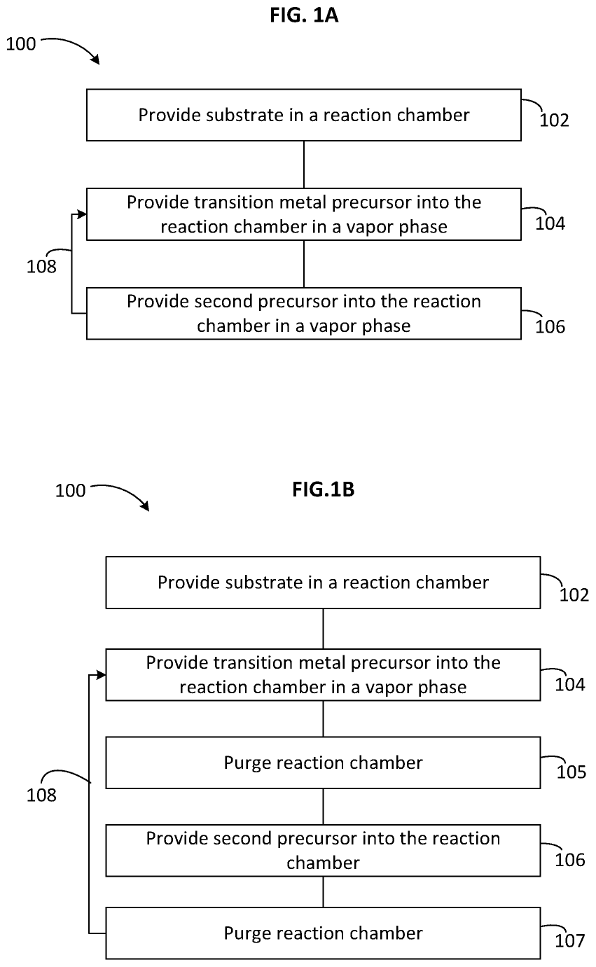

FIG. 1A is a block diagram of an exemplary embodiment of a method 100 of depositing a material comprising a transition metal on a substrate. Method 100 may be used to form a layer comprising a transition metal, i.e. a transition metal layer. The transition metal layer can be used during a formation of a structure or a device, such as a structure or a device described herein. However, unless otherwise noted, methods described herein are not limited to such applications.

In the first phase 102, a substrate is provided in a reaction chamber. A substrate according to the current disclosure comprises a first surface and a second surface. The first surface may be a metal surface or metallic surface. The metal or metallic surface may comprise metal, metal nitrides, metal carbides and/or mixtures thereof, with or without surface oxidation. In some embodiments, the metal or metallic material of the metal or metallic surface is electrically conductive. For example, the first surface may comprise elemental metal, or conductive metal nitride, or conductive metal carbide. The metal comprised in the first surface may be a transition metal. In some embodiments, a metal surface consists essentially of, or consists of one or more metals. Non-limiting exemplary metals of the first surface are Cu, Co, W, Ru, Mo, Ti and V. The metal of the first surface may be substantially completely, or completely in elemental form. Exemplary metal nitrides include TiN and VN. Exemplary metal carbides include TiC, TiAlC and TaC.

The second surface of the substrate may be a dielectric surface, such as a low-k surface. Exemplary low k surfaces include SiOC. The second surface may comprise an oxide, such as silicon oxide. The second surface may comprise silicon, such as SiO₂, or the above-mentioned SiOC. In some embodiments, the second surface comprises carbon. In some embodiments, the second surface comprises silicon, oxygen and carbon.

In some embodiments, a passivation agent, such as silylation, is used to improve contrast between the first surface and the second surface before depositing material comprising a transition metal, such as a transition metal layer, on the first surface. In some embodiments, a second surface may be selectively blocked relative to the first surface, for example, by selectively silylating the second surface. In some embodiments, the second surface is blocked by exposure to a silylation agent, such as alyltrimethylsilane (TMS-A), chlorotrimethylsilane (TMS-C1), N-(trimenthylsilyl)imidazole (TMS-Im), octadecyltrichlorosilane (ODTCS), hexamethyldisilazane (HMDS), or N-(trimethylsilyl)dimethylamine (TMSDMA). Thus, in some embodiments, the second surface is passivated by a silylating agent before depositing a material comprising a transition metal on the first surface. In some embodiments, the silylating agent is selected from a group comprising alyltrimethylsilane (TMS-A), chlorotrimethylsilane (TMS-C1), N-(trimenthylsilyl)imidazole (TMS-Im), octadecyltrichlorosilane (ODTCS), hexamethyldisilazane (HMDS) and N-(trimethylsilyl)dimethylamine (TMSDMA). The passivation may be removed by, for example, a plasma treatment, such as hydrogen plasma treatment. A temperature during the silylation process may be from about 50° C. to about 500° C., or from about 100° C. to about 400° C., such as about 300° C.

The reaction chamber can form part of an atomic layer deposition (ALD) assembly. The assembly may be a single wafer reactor. Alternatively, the reactor may be a batch reactor. Various phases of method 100 can be performed within a single reaction chamber or they can be performed in multiple reaction chambers, such as reaction chambers of a cluster tool or in deposition stations of a multi-station reaction chamber. In some embodiments, the method 100 is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The material comprising a transition metal according to the current disclosure may be deposited in a cross-flow reaction chamber. The material comprising a transition metal according to the current disclosure may be deposited in a showerhead reaction chamber.

During step 102, the substrate can be brought to a desired temperature and pressure for performing the method according to the current disclosure, i.e. providing precursors and/or reactants into the reaction chamber. A temperature (for example temperature of a substrate or a substrate support) within a reaction chamber can be, for example, from about 100° C. to about 500° C., from about 150° C. to about 400° C., from about 200° C. to about 350° C. or from about 150° C. to about 350° C. In an exemplary embodiment, a temperature of 400° C. at most may be used to deposit material comprising a transition metal. The deposition temperature may be limited by the decomposition of a precursor used in the process, and may thus be, for example 280° C., 320° C., 350° C. or 370° C. In some cases, using different temperatures for different precursors may be advantageous. In some embodiments, the reaction chamber comprises a top plate, and the top plate temperature may be lower than the substrate susceptor temperature. For example, a top plate temperature may be at least 50° C. lower than the susceptor temperature. For example, a top plate temperature may be 50° C., 60° C., 70° C. or 80° C. lower than the susceptor temperature. In some embodiments, a susceptor temperature may be at least 200° C., such as about 350° C. or about 370° C.

A pressure within the reaction chamber can be less than 350 Torr, or less than 100 Torr, or less than 50 Ton, or less than 10 Torr. For example, a pressure in the reaction chamber may be about 50 Torr, about 20 Torr, about 5 Ton, about 2 Torr or about 0.1 Torr. Different pressure may be used for different process steps.

Transition metal precursor is provided in the reaction chamber comprising the substrate at phase 104. Without limiting the current disclosure to any specific theory, transition metal precursor may chemisorb on the first surface of the substrate during providing transition metal precursor into the reaction chamber. The duration of providing transition metal precursor into the reaction chamber (transition metal precursor pulse time) may be, for example, 1 s, 2 s, 5 s, 8 s, 10 s, 15 s or 20 s. In some embodiments, the duration of providing transition metal precursor in the reaction chamber (transition metal precursor pulse time) is may be longer than 1 s or longer than 5 s or longer than 10 s. Alternatively, transition metal purge time may be shorter than 60 s, shorter than 30 s, shorter than 10 s, or shorter than 5. For example, for organometallic transition metal precursors comprising aromatic groups, pulse times from about 5 to 15 seconds may be suitable.

When second precursor is provided in the reaction chamber at phase 106, it may react with the chemisorbed transition metal precursor, or its derivate species, to form transition metal on the substrate. The duration of providing second precursor in the reaction chamber (second precursor pulse time) may be, for example 0.1 seconds (s), 0.5 s, 1 s, 3 s, 4 s, 5 s, 7 s, 10 s, 11 s, 15 s or 20 s. In some embodiments, the duration of providing second precursor in the reaction chamber is be shorter than 20 s, shorter than 10 s, shorter than 3 s or about 1 s.

In some embodiments, transition metal precursor may be heated before providing it into the reaction chamber. In some embodiments, second precursor may be heated before providing it to the reaction chamber. In some embodiments, the transition metal precursor may be held in ambient temperature before providing it to the reaction chamber. In some embodiments, the second precursor may be held in ambient temperature before providing it to the reaction chamber.

Stages 104 and 106, performed in any order, may form a deposition cycle, resulting in the deposition of material comprising a transition metal. In some embodiments, the two stages of transition metal deposition, namely providing the transition metal precursor and the second precursor in the reaction chamber (104 and 106), may be repeated (loop 108). Such embodiments may contain several deposition cycles. The thickness of the deposited material comprising a transition metal may be regulated by adjusting the number of deposition cycles. The deposition cycle (loop 108) may be repeated until a desired thickness of material comprising a transition metal is achieved. For example, about 10, 20, 30, 50, 100, 200, 500, or 1,000 deposition cycles may be performed.

The amount of transition metal deposited on the first surface during one cycle (growth per cycle) varies depending on the process conditions, and may be, for example, from about 0.2 Å/cycle to about 5 Å/cycle, 0.3 Å/cycle to about 4 Å/cycle, such as from about 0.5 Å/cycle to about 3 Å/cycle or from about 0.5 Å/cycle to about 2.5 Å/cycle. For example, the growth rate may be about 0.5 Å/cycle, 0.7 Å/cycle, 0.8 Å/cycle, 1.1 Å/cycle, 1.2 Å/cycle, 1.7 Å/cycle, 2 Å/cycle or 2.2 Å/cycle. The rate of deposition may change during a deposition process. For example, in the beginning, such as during the first about 50 deposition cycles, the rate of deposition may be lower than later on during the process. Also, the rate of deposition—at least initially—may vary between surfaces. Without limiting the current disclosure, on metal surfaces, such as on Ru, the rate of deposition may be higher than on conductive metal nitride, such as TiN, surfaces. Also, the lag in the growth initiation may differ between materials, which may be utilized in adjusting the selectivity of the deposition.

Depending on the deposition conditions, deposition cycle numbers etc., transition metal layers of variable thickness may be deposited. For example, a transition metal layer may have a thickness between approximately 0.5 nm and 60 nm, or between about 1 nm and 50 nm, or between about 0.5 nm and 25 nm, or between about 1 nm and 50 nm, or between about 10 nm and 60 nm. A transition metal layer may have a thickness of, for example, approximately 0.2 nm, 0.3 nm, 0.5 nm, 1 nm, 1.5 nm, 2 nm, 2.5 nm, 3 nm, 3.5 nm, 4 nm, 4.5 nm, 5 nm, 6 nm, 8 nm, 10 nm, 15 nm, 20 nm, 25 nm, 30 nm, 35 nm, 40 nm, 50 nm, 70 nm, 85 nm or 100 nm. The desired thickness may be selected according to the application in question.

Transition metal precursor and second precursor may be provided in the reaction chamber in separate steps (104 and 106).

FIG. 1B illustrates an embodiment according to the current disclosure, where phases 104 and 106 are separate by purge 105 and 107. In such embodiments, a deposition cycle comprises one or more purge phases 105, 107. During purge steps, precursor(s) and/or reactant(s) can be temporally separated from each other by inert gases, such as argon (Ar), nitrogen (N₂) or helium (He) and/or a vacuum pressure. The separation of transition metal precursor and second precursor may alternatively be spatial. The temperature and/or pressure within a reaction chamber during phases 102 and 104 can be the same or similar to any of the pressures and temperatures noted above in connection with FIG. 1A. Also the repetition of a deposition cycle 108 may be performed similarly to the embodiments of FIG. 1A.

Purging the reaction chamber 105, 107 may prevent or mitigate gas-phase reactions between a transition metal precursor and a second precursor, or any additional reactants that may be used in the process. Thus, purging may enable and/or enhance self-saturating surface reactions. Surplus chemicals and reaction byproducts, if any, may be removed from the substrate surface, for example by purging the reaction chamber or by moving the substrate, before the substrate is contacted with the next precursor or reactant. In some embodiments, however, the substrate may be moved to separately contact a transition metal precursor and a second precursor. Because in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

The duration of a purge may be, for example 0.1 s, 0.5 s, 1 s, 2 s, 5 s, 7 s, 10 s, 15 s, 25 s, 30 s, 45 s or 60 s. The length of the purge may depend on the processing parameters used during the method, such as precursors used, chamber pressure, temperature and the like.

When performing the method 100, material comprising a transition metal is deposited onto the substrate. The deposition process according to the current disclosure is a cyclic deposition process, and may include cyclic CVD, ALD, or a hybrid cyclic CVD/ALD process. For example, in some embodiments, the growth rate of a particular ALD process may be low compared with a CVD process. Low growth rate may improve the control of the thickness of the transition metal layer. However, in some embodiments, high growth rate may be desired. One approach to increase the growth rate may be that of operating at a higher deposition temperature than that typically employed in an ALD process, resulting in some portion of a chemical vapor deposition process, but still taking advantage of the sequential introduction of a transition metal precursor and a second precursor. Such a process may be referred to as cyclic CVD. In some embodiments, a cyclic CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process. In accordance with further examples, a cyclic deposition process may comprise the continuous flow of one precursor or reactant, and the periodic pulsing of the other chemical component into the reaction chamber.

In some embodiments, the transition metal precursor is brought into contact with a substrate surface at 104, excess transition metal precursor is partially or substantially completely removed by an inert gas or vacuum at 105, and second precursor is brought into contact with the substrate surface comprising transition metal precursor and/or a derivative thereof. Transition metal precursor may be brought in to contact with the substrate surface in one or more pulses 104. In other words, pulsing of the transition metal precursor 104 may be repeated. The transition metal precursor on the substrate surface may react with the second precursor to form transition metal on the substrate surface. Also pulsing of the second precursor 106 may be repeated. In some embodiments, second precursor may be provided in the reaction chamber first at phase 106. Thereafter, the reaction chamber may be purged 105 and transition metal precursor provided in the reaction chamber in one or more pulses 104.

In some embodiments, transition metal layer according to the current disclosure may have a resistivity of about 600 μΩ cm or less. The thickness of a layer with said resistivity may be, for example, from about 10 nm to about 25 nm. For metal nitrides (such as MoN), the resistivity may be higher than indicated, and the lowest resistivities are typically achieved with materials comprising elemental metal to a large extent (such as metallic Mo).

Resistivity of a transition metal layer may be reduced by using a post-deposition anneal. Annealing may be performed directly after deposition of a transition metal layer, i.e. without additional layers being deposited. Alternatively, annealing may be performed after additional layers have been deposited. A transition metal layer may be capped before annealing. A capping layer may comprise, consist essentially of, or consist of silicon nitride. An annealing temperature from about 320° C. to about 500° C. could be used. For example, an annealing temperature may be 330° C., 350° C., 380° C., 400° C., 430° C. or 450° C. or 470° C. Annealing may be performed in a gas atmosphere comprising, consisting essentially of, or consisting of argon, argon-hydrogen mixture, hydrogen, nitrogen or nitrogen-hydrogen mixture. Duration of annealing may be from about 1 minute to about 60 minutes, for example 5 minutes, 20 minutes, 30 minutes or 45 minutes. An annealing may be performed at a pressure of 0.05 to 760 Torr. For example, a pressure during annealing may be about 1 Torr, about 10 Torr, about 100 Torr or about 500 Torr.

For clarity, the order of phases depicted in FIG. 1, panels A and B, is exemplary only, and the order of the precursors and reactants, as well as the loop repetitions may be selected according to the specific embodiment at hand. Specifically, in some embodiments, providing a second precursor 106 in the beginning of the process may be beneficial for the material layer growth.

The properties of the material comprising a transition metal depend on the deposition parameters, such as the precursors and reactants, cycling scheme, and temperature and pressure during deposition. For example, for transition metal nitride, a carbon content of 10 at. % or less, for example about 5 at- % or about 7 at. % may be achieved.

The ratio of nitrogen to transition metal in the deposited material may vary. In some embodiments, the nitrogen to metal ratio may be about 0.7 to 1.0. However, in some embodiments, the nitrogen to metal ratio may be about 0.5, or about 0.3, meaning that the material may have a higher amount of metal compared to nitrogen. The higher metal content relative to nitrogen may correlate with lowered carbon content.

In some non-limiting exemplary experiments, selective deposition of material comprising a transition metal was performed. In certain experiments, molybdenum was deposited on a first surface, wherein the first surface was a copper surface. The second surface was a SiOC-comprising low k surface.

In one set of exemplary tests, molybdenum-comprising material was deposited. Bis(ethylbenzene)molybdenum was used as the transition metal precursor, and molecular hydrogen was used as the second precursor. Molybdenum-comprising material was deposited on copper surface, tungsten surface and titanium nitride surface, whereas no growth was observed on low k material at 750 deposition cycles. Some deposition was observed on thermal silicon oxide and native silicon oxide, but the growth initiation was very slow, and a window for selective deposition was identified. The deposition temperature had an effect on the carbon content of the deposited molybdenum-comprising material on metal surfaces, which was about 20 to 28 At-% at a deposition temperature of 225° C., and about 30 to 40 At-% at a deposition temperature of 300° C. However, on TiN surface, the carbon content of the deposited material was lower, about 14 to 15 At-%.

In another set of exemplary tests, molybdenum-comprising material was deposited. Bis(ethylbenzene)molybdenum was used as the transition metal precursor, and 1,2-diiodoethane was used as the second precursor. Argon was used as the carrier gas during deposition. Molybdenum-comprising material was deposited on ruthenium surface, hafnium oxide surface and TiN surface. About 3 nm growth on the ruthenium surface was observed at about 30 deposition cycles, the layer thickness increasing to about 6 nm at 50 cycles and to about 9 nm at 75 cycles, and to about 15 nm at 100 cycles. On TiN and HfO₂ surface, growth (about 3 nm) was observed at 50 deposition cycles, and both reached thickness of about 12 to 13 nm at 100 deposition cycles. On thermal silicon oxide, growth started significantly later, and on low k, no growth was observed until the end of the test at 100 deposition cycles. The temperature at this set of experiments was about 350° C. and the chamber pressure 2 Torr. In another test, molybdenum growth on Cu was confirmed with this precursor pair.

In yet another experiment, bis(ethylbenzene)molybdenum was used as the transition metal precursor, and tert-butylhydrazine as the second precursor. In this case, the second precursor was a nitrogen precursor, as the deposited material comprised molybdenum nitride. The deposition was performed in several temperatures ranging from 200° C. to 300° C. The rate of deposition varied between 0.45 and 1 Å/cycle. The resisitivity of the deposited material varied from over 10,0001112 cm (material deposited at 200° C.) to about 1,8001112 cm (material deposited at 300° C.). On thermal oxide, a long incubation time before growth initiation was observed relative to the metallic surface, allowing for the selective deposition on a first surface relative to a second surface.

In a yet further experiment, hexamethyldisilane was used as the second precursor with bis(ethylbenzene)molybdenum, at deposition temperatures from 260° C. to 350° C. With this combination, the deposition on dielectric materials and on metallic materials was similar as to experiments in which H₂ was used as second precursor. Thus, no growth was observed on native silicon oxide or thermal silicon oxide, whereas on Ru, TiN, Cu and W, as well as on an alloy of Co and Cu, a material layer was observed.

The effect of passivating the second surface was tested by treating a patterned test structure containing copper lines and low k areas with TMSDMA prior to deposition. The passivation treatment was performed up to 10 days prior to depositing molybdenum on the test structures.

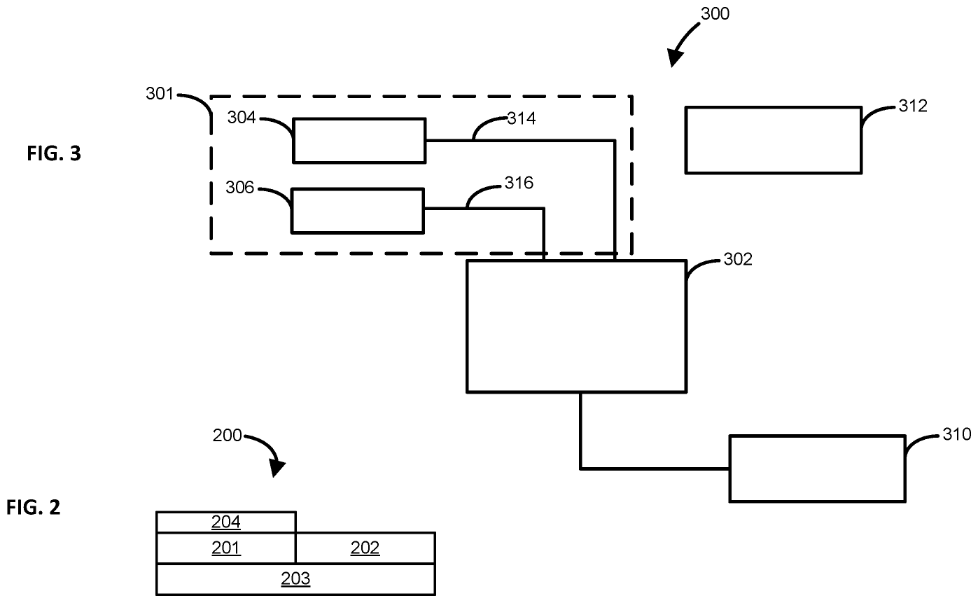

FIG. 2 illustrates an exemplary structure, or a portion of a device, 200 in accordance with the disclosure in a schematic manner. Portion of a device or structure 200 includes a substrate 203 comprising a first surface 201 and a second surface 202. A transition metal layer 204 is deposited on the first surface 201, but not on the second surface 202. The first surface 201 and the second surface 202 may comprise or consist of materials described herein.

A material comprising a transition metal 204 is deposited selectively on a first surface of a substrate 201 relative to a second surface of the same substrate 202. In the drawing, a substrate 203 comprising a first surface 201 and a second surface 202 is depicted. The first surface 201 may be, for example, a metal surface, such as Cu or Ru surface, as explained in more detail above. The second surface 202 may be, for example, a dielectric surface, such as SiOC or other low k material surface. Although the two surfaces are schematically presented as being in one plane, of equal thickness and positioned directly on the substrate 203, other configurations of the first surface 201 and second surface 202 are possible. For example, one of them may be lower or higher than the other, and one or both of them may comprise three-dimensional structures, and there may be one or more additional layers between the substrate 203 and the surface in question. Further, there may be additional surfaces present on the substrate, and one or more of the surfaces on the substrate 203 may be partially embedded in the substrate 203 material.

During the deposition of the material comprising a transition metal 204, the second surface 202 may be passivated. For example, a passivation layer, such as silylation may be present on the second surface 202. The passivation may be removed at the end of the selective deposition process, so the passivation material is not depicted in FIG. 2.

Because the material comprising a transition metal 204 is deposited selectively on the first surface 201, any material comprising a transition metal 204 on the second surface 202 will be thinner than the material comprising a transition metal 204 deposited on the first surface 201. Accordingly, the etch-back can be used to remove all, or substantially all, of the undesired deposited material from over the second surface 202 without removing all of the material comprising a transition metal 204 from over the first surface 201. Repeated selective deposition and etching back in this manner can result in an increasing thickness of the material comprising a transition metal 204 on the first surface 201 with each cycle of deposition and etch. Alternatively or in addition to such an intermittent etch-back, an etch-back may be performed at the end of the deposition process. This may have the advantage of removing the passivation from the second surface 202, possibly allowing further deposition processes to be performed on the substrate.

FIG. 2 depicts the substrate 203 after a post-deposition treatment, such as an etch-back, to remove the passivation from the second surface 202. In some embodiments, the etch-back may comprise exposing the substrate 203 (and any layers on it) to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch-back may comprise exposing the substrate to an etchant comprising oxygen, for example O₃. In some embodiments, the substrate may be exposed to an etchant at a temperature of between about 30° C. and about 500° C., or between about 100° C. and about 400° C. In some embodiments, the etchant may be supplied in one continuous pulse or may be supplied in multiple pulses. The removal of the passivation layer can be used to lift-off any remaining material comprising a transition metal 204 from over the second surface 202, either in a complete removal of the passivation layer or in a partial removal of the passivation layer in a cyclical selective deposition and removal.

FIG. 3 illustrates a vapor processing assembly 300 according to the current disclosure in a schematic manner. Deposition assembly 300 can be used to perform a method as described herein and/or to form a structure or a device, or a portion thereof as described herein.

In the illustrated example, processing assembly 300 includes one or more reaction chambers 302, a precursor injector system 301, a transition metal precursor vessel 304, second precursor vessel 306, an exhaust source 310, and a controller 312. The processing assembly 300 may comprise one or more additional gas sources (not shown), such as an inert gas source, a carrier gas source, additional reactant source(s) and/or a purge gas source.

Reaction chamber 302 can include any suitable reaction chamber, such as an ALD or CVD reaction chamber as described herein.

The transition metal precursor vessel 304 can include a vessel and one or more transition metal precursors as described herein—alone or mixed with one or more carrier (e.g., inert) gases. Second precursor vessel 306 can include a vessel and one or more second precursors as described herein—alone or mixed with one or more carrier gases. Although illustrated with two source vessels 304 and 306, vapor processing assembly 300 can include any suitable number of source vessels. Source vessels 304 and 306 can be coupled to reaction chamber 302 via lines 314 and 316, which can each include flow controllers, valves, heaters, and the like. In some embodiments, the transition metal precursor in the transition metal precursor vessel 304, the second precursor in the second precursor vessel 306 and/or an additional reactant in an optional additional reactant vessel (not shown) may be heated. In some embodiments, a vessel is heated. Each vessel may be heated to a different temperature, according to the precursor or reactant properties, such as thermal stability and volatility.

Exhaust source 310 can include one or more vacuum pumps.

Controller 312 includes electronic circuitry and software to selectively operate valves, manifolds, heaters, pumps and other components included in the processing assembly 300. Such circuitry and components operate to introduce precursors, reactants and purge gases from the respective sources. Controller 312 can control timing of gas pulse sequences, temperature of the substrate and/or reaction chamber 302, pressure within the reaction chamber 302, and various other operations to provide proper operation of the processing assembly 300. Controller 312 can include control software to electrically or pneumatically control valves to control flow of precursors, reactants and additional gases into and out of the reaction chamber 302. Controller 312 can include modules such as a software or hardware component, which performs certain tasks. A module may be configured to reside on the addressable storage medium of the control system and be configured to execute one or more processes.

Other configurations of vapor processing assembly 300 are possible, including different numbers and kinds of precursor and reactant sources. Further, it will be appreciated that there are many arrangements of valves, conduits, precursor sources, and additional reactant sources that may be used to accomplish the goal of selectively and in coordinated manner feeding gases into reaction chamber 302. Further, as a schematic representation of a vapor processing assembly, many components have been omitted for simplicity of illustration, and such components may include, for example, various valves, manifolds, purifiers, heaters, containers, vents, and/or bypasses.

During operation of vapor processing assembly 300, substrates, such as semiconductor wafers (not illustrated), are transferred from, e.g., a substrate handling system to reaction chamber 302. Once substrate(s) are transferred to reaction chamber 302, one or more gases from gas sources, such as precursors, reactants, carrier gases, and/or purge gases, are introduced into reaction chamber 302.

In some embodiments, the transition metal precursor is supplied in pulses, a second precursor is supplied in pulses and the reaction chamber is purged between consecutive pulses of transition metal precursor and second precursor.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing material comprising a group 3 to 6 transition metal on a first surface of a substrate relative to a second surface of the substrate by a cyclic deposition process, the method comprising
providing a substrate in a reaction chamber;
providing a transition metal precursor into the reaction chamber in a vapor phase, wherein the transition metal precursor comprises an aromatic ligand; and
providing a second precursor into the reaction chamber in a vapor phase, to deposit transition metal on the first surface of the substrate.

2. The method of claim 1, wherein the transition metal precursor comprises a benzene or a cyclopentadienyl group.

3. The method of claim 1, wherein the transition metal precursor comprises only a transition metal, carbon, and hydrogen.

4. The method of claim 1, wherein the transition metal precursor comprises an ethylbenzene ligand.

5. The method of claim 1, wherein the second precursor comprises a reducing agent.

6. The method of claim 5, wherein the reducing agent comprises molecular hydrogen (H₂).

7. The method of claim 1, wherein the second precursor comprises a halogenated hydrocarbon.

8. The method of claim 7, wherein the halogenated hydrocarbon comprises two halogen atoms attached to adjacent carbon atoms of a carbon chain.

9. The method of claim 8, wherein the halogenated hydrocarbon is a 1,2-dihaloalkane, a 1,2-dihaloalkene, a 1,2-dihaloalkyne or a 1,2-dihaloarene.

10. The method of claim 9, wherein the halogenated hydrocarbon is 1,2-diiodoethane.

11. The method of claim 1, wherein the first surface is a metal or metallic surface.

12. The method of claim 11, wherein the metal or metallic surface is selected from the group consisting of Mo, W, Ru, Co, Cu, TiN, VN and TiC.

13. The method of claim 1, wherein the second surface is a dielectric surface.

14. The method of claim 13, wherein the dielectric surface comprises silicon.

15. The method of claim 14, wherein the second surface is a silicon oxide-based surface.

16. The method of claim 13, wherein the dielectric surface is a low k surface.

17. The method of claim 1, wherein the second surface is treated with a passivating agent before providing the transition metal precursor into the reaction chamber.

18. The method of claim 17, wherein the passivating agent comprises a silylating agent.

19. The method of claim 18, wherein the silylating agent is selected from the group consisting of alyltrimethylsilane (TMS-A), chlorotrimethylsilane (TMS-C1), N-(trimenthyl silyl)imidazole (TMS-Im), octadecyltrichlorosilane (ODTCS), hexamethyldisilazane (HMDS), and N-(trimethylsilyl)dimethylamine (TMSDMA).

20. The method of claim 1, wherein the cyclic deposition process comprises a thermal deposition process.

21. The method of claim 1, wherein transition metal is deposited on the first surface of the substrate as a layer.

22. The method of claim 1, wherein the transition metal is molybdenum, and the transition metal is selectively deposited on a metal surface inside a feature.

23. A vapor deposition assembly for selectively depositing material comprising a group 3 to 6 transition metal on a first surface of a substrate relative to a second surface of the substrate, the vapor processing assembly comprising:
one or more reaction chambers constructed and arranged to hold the substrate;
a precursor injector system constructed and arranged to provide a transition metal precursor comprising an aromatic ligand and a second precursor into the reaction chamber in a vapor phase;
wherein the vapor deposition assembly comprises a precursor vessel constructed and arranged to contain a transition metal precursor comprising an aromatic ligand;
and wherein the vapor processing assembly is constructed and arranged to provide the transition metal precursor and the second precursor via the precursor injector system to the reaction chamber to deposit material comprising transition metal selectively on the first surface of the substrate relative to the second surface of the substrate.

24. The vapor processing assembly of claim 23, wherein the vapor processing assembly further comprises a passivating agent source constructed and arranged to contain a passivating agent for passivating the second surface of the substrate, and wherein the precursor injector system is constructed and arranged to provide the passivating agent into the reaction chamber in vapor phase.
